(19) United States
(12) Patent Application Publication
(10) Pub. No.: US 2026/0206327 A1
(43) Pub. Date: Jul. 16, 2026

(54) LATCH-UP CIRCUIT CAPABLE OF SUPPRESSING TRIGGER, AND STRUCTURE OF SEMICONDUCTOR SUBSTRATE COMPRISING LATCH-UP CIRCUIT CAPABLE OF SUPPRESSING TRIGGER

(71) Applicant: LX SEMICON CO., LTD., Daejeon (KR)

(72) Inventors: Jae Hyun LEE, Daejeon (KR); Yong Nam CHOI, Daejeon (KR)

(73) Assignee: LX SEMICON CO., LTD., Daejeon (KR)

(21) Appl. No.: 19/137,162

(22) PCT Filed: Jul. 25, 2023
(86) PCT No.: PCT/KR2023/010765

§ 371 Date: Jun. 9, 2025

(30) Foreign Application Priority Data
Dec. 7, 2022 (KR) 10-2022-0169609
Jun. 19, 2023 (KR) 10-2023-0077978

(51) Int. Cl. H10D 89/60; H10D 1/43; H10D 10/60; H10D 62/10; H10D 84/60

(52) U.S. Cl. CPC H10D 89/713; H10D 1/43; H10D 10/60; H10D 62/102; H10D 62/124; H10D 84/619; H10D 89/911

(57) ABSTRACT

The present invention proposes a latch-up circuit capable of suppressing a trigger operation of a latch-up circuit formed by a parasitic bipolar transistor and a parasitic resistor in a semiconductor substrate on which a plurality of wells are formed, and a semiconductor structure having a structure capable of suppressing a trigger operation of a latch-up circuit.

### TECHNICAL FIELD

The present invention relates to a latch-up circuit, and more particularly, to a latch-up circuit including an additional parasitic resistance capable of suppressing a trigger operation of a latch-up circuit formed by a parasitic bipolar transistor and a parasitic resistor of a semiconductor substrate having a plurality of wells formed therein, and a structure of a semiconductor substrate including the latch-up circuit.

### BACKGROUND

A CMOS circuit is a circuit that uses a P-type MOS transistor and an N-type MOS transistor at the same time. A semiconductor integrated circuit including components of a CMOS circuit can be implemented by first forming at least two wells on a semiconductor substrate, integrating a P-type MOS transistor in the N-type well, integrating an N-type MOS transistor in the P-type well, and electrically connecting the P-type MOS transistor and the N-type MOS transistor according to the circuit configuration.

FIG. 1 illustrates two wells that implement a conventional CMOS circuit and the power supply applied to them.

Referring to FIG. 1, a high voltage N type well 120, a high voltage P type well 130, and a high voltage N type well 140 are formed on the substrate 110, and a high voltage power supply (HV Power) of 18V, a low voltage power supply (LV Power) of 1.8V, and a ground power supply (GND) are applied, respectively.

In general, the latch-up phenomenon is caused by the structure of a semiconductor substrate in which multiple wells are formed.

Referring to FIG. 1, the vertical and horizontal structures of multiple regions formed on the semiconductor substrate correspond to two bipolar transistors (PNP, NPN) and multiple resistors (RHV P-Well, REmitter), and the latch-up circuit is expressed as a corresponding circuit for these components (PNP, NPN, RHV P-Well, REmitter), and the latch-up circuit is not intended by the semiconductor circuit designer.

FIG. 2 illustrates the latch-up circuit illustrated in FIG. 1 separately.

Referring to FIG. 2, the latch-up circuit is a closed loop circuit formed by two bipolar transistors (PNP, NPN) and two resistors (RHV P-Well, REmitter).

Since the operation and electrical characteristics of the latch-up circuit have already been disclosed in multiple patents and multiple documents, including Korean Patent No. 10-0641954 (Oct. 26, 2006), only the operation characteristics are briefly described here to help understanding of the present invention.

For convenience of explanation, the flow of current is described in the same direction as the flow of holes, and in FIGS. 1 and 2, holes are depicted as + marks located inside a circle.

Referring to FIG. 1 and FIG. 2, the active region (P+) and the high voltage P type well (130) that supply the ground voltage (GND) to the high voltage P type well 130 correspond to the base terminal of the second bipolar transistor (NPN), and the low voltage N type well (140) corresponds to the emitter terminal.

In order to suppress the operation of the first bipolar transistor (PNP) and the second bipolar transistor (NPN), an alternative method of increasing the resistance value (resistance) of the emitter resistor (REmitter) formed between the emitter terminal of the second bipolar transistor (NPN) and the low voltage power supply (LV Power) terminal by increasing the area of the high voltage P type well 130 may be suggested.

Increasing the area of the high-voltage P-type well 130 here means increasing the width (Wwidth) of the high-voltage P-type well 130, and means increasing the distance between the emitter terminal of the second bipolar transistor (NPN) and the low-voltage power supply (LV Power) terminal. This alternative increases the area used on the semiconductor substrate, and therefore does not conform to the recent technological trend of trying to reduce the size of the chip.

### DISCLOSURE OF THE INVENTION

### Technical Problem

The technical problem to be solved by the present invention is to provide a structure of a semiconductor substrate having a structure including an additional parasitic resistance capable of suppressing a trigger operation of a latch-up circuit formed by a parasitic bipolar transistor and a parasitic resistor of a semiconductor substrate having a plurality of wells formed.

### Technical Solution

According to one aspect of the present invention for achieving the above technical problem, a semiconductor substrate structure may include a first bipolar transistor, a second bipolar transistor, and an emitter resistor, and include a latch-up circuit capable of suppressing a trigger which has a structure that increases a resistance value of the emitter resistor formed between an emitter terminal of the second bipolar transistor and a low-voltage power supply or forms an additional resistance between the emitter terminal of the second bipolar transistor and the emitter resistor.

According to another aspect of the present invention for achieving the above technical problem, a semiconductor substrate structure may include a first bipolar transistor, a second bipolar transistor, and an emitter resistor, wherein the second bipolar transistor has a first well as a base region, a second well of a different type from the first well as an emitter region, and include a latch-up circuit capable of suppressing a trigger that increase the resistance value of the emitter resistor or form the additional resistance by utilizing at least one of the number of contact fillers formed between a power supply active region formed in the second well and the contact line located above the power supply active region, an installation location of a contact filler and a blocking film covering a portion of an upper portion of the power supply active region is formed.

### Effect of the Invention

The structure of the semiconductor substrate including the latch-up circuit capable of suppressing a trigger according to the present invention as described above and the latch-up circuit capable of suppressing a trigger has the advantage of being able to increase or add the resistance value of the emitter resistor that suppresses triggering the latch-up circuit without adding a process or mask.

### BRIEF DESCRIPTION OF THE DRAWINGS

FIG. 1 illustrates two wells implementing a conventional CMOS circuit and the power supply applied to them.

FIG. 2 illustrates the latch-up circuit shown in FIG. 1 separately.

FIG. 3 illustrates one embodiment of the latch-up circuit capable of suppressing a trigger according to the present invention.

FIG. 4 illustrates the structure of the semiconductor substrate in which the latch-up circuit capable of suppressing a trigger according to the present invention is parasitically generated.

FIG. 5 illustrates the structure of another embodiment of the semiconductor substrate including the latch-up circuit capable of suppressing a trigger according to the present invention.

### BEST MODE

In order to fully understand the present invention and its operational advantages and the purpose achieved by the practice of the present invention, reference should be made to the attached drawings and the contents described in the attached drawings, which illustrate exemplary embodiments of the present invention.

Hereinafter, the present invention will be described in detail by describing preferred embodiments of the present invention with reference to the attached drawings. The same reference numerals presented in each drawing represent the same components.

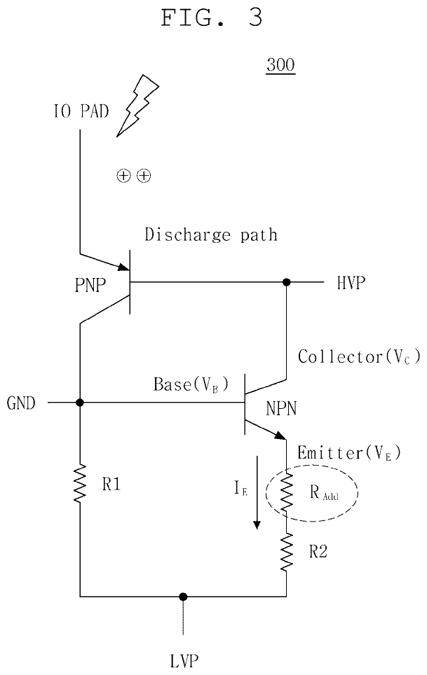

FIG. 3 illustrates one embodiment of a latch-up circuit capable of suppressing a trigger according to the present invention.

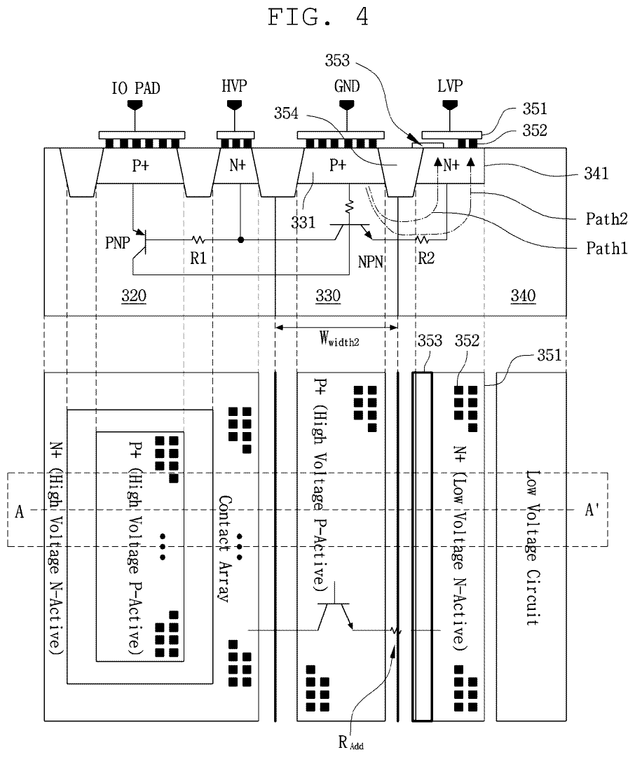

FIG. 4 illustrates the structure of a semiconductor substrate in which a latch-up circuit capable of suppressing a trigger according to the present invention is parasitically generated.

The upper part of FIG. 4 is a vertical cross-sectional view (A-A′) of the semiconductor substrate, and the lower part is a plan view.

Referring to FIG. 3, a latch-up circuit (hereinafter, latch-up circuit, 300) capable of suppressing a trigger according to the present invention includes a first bipolar transistor (PNP), a second bipolar transistor (NPN), a first collector resistor (R1), a first emitter resistor (R2), and an additional resistance (R_{Add}).

As described above when explaining the conventional technology, the latch-up circuit 300 illustrated in FIG. 3 is parasitically generated by the vertical and horizontal structures of the semiconductor substrate, and is not a circuit designed by a circuit designer, and the additional resistance (R_{Add}) proposed to be added in the present invention is not included in the circuit designed by the designer.

Referring to FIG. 3 and FIG. 4, it can be seen that the emitter terminal and the base terminal of the first bipolar transistor (PNP), and the first collector resistor (R1) are formed in the high voltage N type well 320 region, the collector terminal of the first bipolar transistor (PNP) and in the base terminal of the second bipolar transistor (NPN) are formed in the high voltage P type well 330 region, and the emitter terminal of the second bipolar transistor (NPN) is formed in the low voltage N type well 340 region.

The first bipolar transistor (PNP) has an emitter terminal connected to an input/output pad (IO PAD), a base terminal connected to a high voltage power supply (HVP), and a collector terminal connected to a ground power supply (GND).

The second bipolar transistor (NPN) has a collector terminal connected to a high voltage power supply (HVP) and a base terminal connected to a ground power supply (GND).

The first collector resistor (R1) is connected between the collector terminal of the first bipolar transistor (PNP) and the low voltage power supply (LVP).

The first emitter resistor (R2) is installed between one terminal of the low voltage power supply (LVP).

The additional resistance (R_{Add}) is installed between the emitter terminal of the second bipolar transistor (NPN) and the other terminal of the first emitter resistor (R2).

Here, the expression that the resistor is installed between two terminals means the same as that the resistor electrically connects the two terminals. That is, the first emitter resistor (R2) connects the additional resistance (R_{Add}) to the low voltage power supply (LVP) while having a constant resistance value.

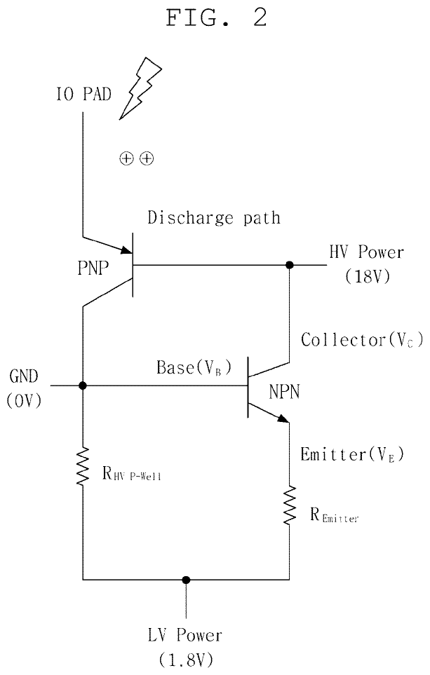

Referring to FIG. 4, the additional resistance (R_{Add}) can be generated by a blocking film 353 formed in the space between the contact line 351 supplying the low voltage power supply (LVP) and the active region 341 used to supply power to the low voltage N type well 340. The additional resistance (R_{Add}) is used to mean that it is added between the first emitter resistor (R2), which is a resistor connected to the emitter terminal of the second bipolar transistor (NPN), but it is also the same as the concept that the resistance value of the emitter resistor (R_{Emitter}) increases in the conventional latch-up circuit illustrated in FIG. 2.

The resistance value of the first emitter resistor (R2) is proportional to the length between the active region 331 formed in the high voltage P type well 330 and the active region 341 formed in the low voltage N type well 340.

To help understanding, it is assumed that charges move in the direction of the arrow along two movement paths (Path1, Path2) between the active region 331 formed in the high-voltage P-type well 330 and the active region 341 formed in the low-voltage N-type well 340 in FIG. 4. The resistance value corresponding to the first path (Path1) where the movement distance of the charges is shorter than the second path (Path2) between the two active regions 331, 341 will be smaller than the resistance value corresponding to the second path (Path2) where the movement length of the charges is longer than the first path (Path1).

Referring to FIG. 4, it can be seen that the first path (Path1) and the second path (Path2) are determined according to the position of the contact filler 352 formed in the space between the contact line 351 supplying the low-voltage power supply (LVP) and the active region 341. That is, the place where there is no contact filler 352 becomes the first path (Path1), and the place where the contact filler 352 is formed becomes the second path (Path2).

Here, the contact filler 352 is a means of electrically connecting the contact line 351 and the active region 341 by filling the hole (not shown) formed between the contact line 351 and the active region 341 with a conductive material such as metal.

For example, the place where there is no contact filler 352 is an area in contact with the field oxide film 354 formed between the high voltage P type well 330 and the low voltage N type well 340, and the place where the contact filler 352 is formed will be a place a certain distance away from the field oxide film 354.

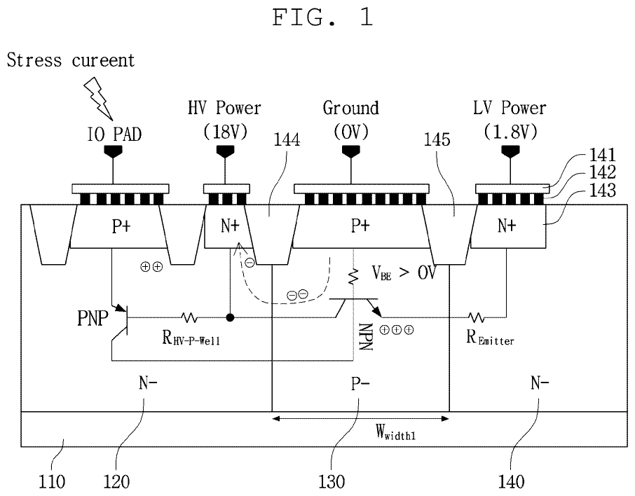

Referring to FIG. 1, since a plurality of contact fillers 142 are widely formed in the space between the contact line 141 supplying the low voltage power supply (LVP) and the active region 143 in the past, the resistance value of the first emitter resistor (R2) was a parallel sum of the resistance values of the first path (Path1) and the second path (Path2). That is, in the case of FIG. 1, since the charge can move through the first path (Path1) and the second path (Path2), the resistance value of the first emitter resistor (R2) should consider the charge that moves through the two paths (Path1, Path2).

In the present invention, since the contact filler 352 does not exist at one end of the first path (Path1), the movement length increases compared to the first path (Path1) illustrated in FIG. 1, which will increase the resistance value of the emitter resistor connected to the emitter terminal of the second bipolar transistor (NPN). Here, since there is no contact filler 352 at the end of the additional resistance (R_{Add}), the resistance value of the additional resistance (R_{Add}) formed and the first emitter resistance (R2) can be the sum.

The present invention also has to consider both paths (Path1, Path2), but the resistance value of the first path (Path1) and therefore the additional resistance (R_{Add}) in the present invention illustrated in FIG. 4 is greater than the resistance value of the first path (Path1) in the conventional technology illustrated in FIG. 1. Therefore, when the resistances on the two paths are combined in parallel, the emitter resistance value of the second bipolar transistor (NPN) in the present invention will be greater than the emitter resistance value of the conventional technology.

In addition, as the number of contact fillers 352 decreases and the contact fillers 352 are formed farther away from the field oxide film 354, it is clear that the resistance value of the first emitter resistance (R2) will increase. When a plurality of contact fillers 352 are formed, assuming that the distance between the contact filler 352 furthest from the field oxide film 354 and the field oxide film 354 is 1 (one), it is preferable that the contact filler 352 formed closest to the field oxide film 354 be about 0.1 to 0.5 away from the field oxide film 354 in order to increase the resistance value of the first emitter resistor (R2). The number and formation location of the contact fillers 352 can be determined by a mask defining the contact fillers 352.

The present invention proposes that by forming a blocking film 353 in the space between a contact line 351 supplying a low voltage power supply (LVP) and an active region 341, a silicide layer is not formed in the lower region of the blocking film 353, thereby increasing the surface resistance of the diffusion region 341 corresponding to the blocking film 353, and at the same time, a contact filler 352 is not formed in the corresponding region, thereby increasing the path for moving charges by forming the contact filler at a location far from the field oxide film 354, and ultimately increasing the resistance value of the first emitter resistor (R2) by reducing the number of contact fillers 352. Referring to FIG. 4, the blocking film 353 can cover a part of the field oxide film 354 and an upper part of the power supply active region that is in contact with the field oxide film 354.

As described above, as the resistance value of the first emitter resistor (R2) increases, the operation initiation (trigger) of the latch-up circuit 300 illustrated in FIG. 3 becomes more difficult.

In the previous example, for ease of understanding, two paths (Paht1, Path2) were assumed and explained. Since the charge forming the current mostly moves along the surface of the conductor, the resistance value of the resistance due to the additional resistance (R_{Add}) or the first path (Path1) increases the resistance value of the path moving to the contact line 351 by the blocking film 353.

That is, the absence of the silicide layer that is not formed by the blocking film 353 increases the resistance value of the resistance seen from the emitter terminal of the second bipolar transistor (NPN).

Below, the relationship between the resistance value of the emitter resistor connected to the emitter terminal of the second bipolar transistor (NPN) and the trigger of the latch-up circuit is explained.

For convenience of explanation, it is assumed that the voltage level of the high voltage power supply (HVP) is 18 V, the voltage level of the low voltage power supply (LVP) is 1.8 V, and the voltage level of the ground power supply (GND) is 0 V (zero volt).

In the above explanation, the first bipolar transistor (PNP), the second bipolar transistor (NPN), the first collector resistor (R1), the first emitter resistor (R2), and the additional resistance (R_{Add}) are not circuit elements included in the circuit that the designer wants to implement, but are parasitic elements automatically generated by the vertical and horizontal patterns of the semiconductor substrate, and the word parasitic was not included to simplify the terminology.

In order for two bipolar transistors (PNP, NPN) to be continuously turned on while complementing each other by the current applied from the outside to the input/output pad (IO PAD), a moment (trigger) for the second bipolar transistor (NPN) that was turned off to turn on is absolutely necessary. In order for the second bipolar transistor (NPN) to turn on, the voltage level (V_{B}) of the base terminal of the second bipolar transistor (NPN) must be 0.7 V or higher than the voltage level (V_{E}) of the emitter terminal. Here, 0.7 V is the threshold voltage, which is the condition for the second bipolar transistor (NPN) to turn on, and may vary depending on the process conditions, and is specific for the convenience of explanation.

Referring to FIG. 3, the voltage level (V_{E}) of the emitter terminal of the second bipolar transistor (NPN) becomes the same as the voltage level of the low voltage power supply (LVP) before the second bipolar transistor (NPN) is turned on. In order for the second bipolar transistor (NPN) to be turned on, the base-emitter voltage level (V_{BE}), which is the difference voltage between the voltage level (V_{B}) of the base terminal of the second bipolar transistor (NPN) and the voltage level (V_{E}) of the emitter terminal, must be 0.7 V or higher.

The turn-on condition (V_{BE}) of the second bipolar transistor (NPN) can be derived through a process such as mathematical expression 1.

$${V}_{B} > {V}_{E} - 0.7 V \qquad [ Mathmatical Expression 1 ]$$

$${V}_{E} = {I}_{E} X ( {R}_{Add} + {R}_{2} )$$

$${V}_{B E} ( {V}_{B} - {V}_{E} ) > 0.7 V + {I}_{E} X ( {R}_{Add} + {R}_{2} )$$

Referring to the mathematical expression 1, it can be seen that the voltage level (V_{E}) of the emitter terminal of the second bipolar transistor (NPN) is determined by the sum of the first emitter resistance (R2) and the additional resistance (R_{Add}). Here, the first emitter resistance (R2) is the same as the resistance in the conventional structure, and the additional resistance (R_{Add}) is proposed in the present invention.

That is, by forcibly generating an additional resistance (R_{Add}) between the emitter terminal of the second bipolar transistor (NPN) and the first emitter resistor (R2) in the present invention, it can be seen that the voltage level (V_{B}) of the base terminal of the second bipolar transistor (NPN), which is a trigger condition for turning on the second bipolar transistor (NPN), must be added by the voltage level corresponding to the product of the first emitter resistance (R2) and the emitter current (I_{E}) plus the sum of 0.7 V and the voltage level corresponding to the product of the emitter current (I_{E}) flowing through the additional resistance (R_{Add}).

In the conventional structure without the additional resistance (R_{Add}) proposed in the present invention, if the voltage level (V_{B}) of the base terminal of the second bipolar transistor (NPN) is greater than the sum of the voltage level corresponding to the product of the first emitter resistance (R2) and the emitter current (I_{E}) and 0.7 V, the second bipolar transistor (NPN) is turned on.

In the present invention, the contact filler 352 is not formed in the location where the blocking film 353 is formed as shown in FIG. 4, so that the additional resistance (R_{Add}) can be added in the latch-up circuit.

If the blocking film 353 that specifies the location where the additional resistance (R_{Add}) is formed requires an additional mask (MASK) or an additional process, the effect and manufacturing cost when the additional resistance (R_{Add}) is introduced should be compared, and the present invention also proposes a method that can use the existing mask and process as they are below.

Silicide is a compound of silicon and metal, and is used to lower the resistance of the gate electrode or the contact resistance of the source/drain junction during the semiconductor manufacturing process. Tungsten (W), molybdenum (Mo), and cobalt (Co) are used as metals.

The present invention proposes to use the silicide generation and etching process that is already in use, which is performed before the process of generating the contact filler 352. In other words, it proposes to use the silicide process that is already in use to use the silicide film (silicide block) as a blocking film 353.

Salicide is a compound word of self-aligned silicide, and it is named so because the metal to be used for silicide is deposited and then heat treated, so that silicide is generated only in the part where the metal and silicon come into contact, and the metal that does not react with silicon after the heat treatment can be removed through selective etching. That is, a separate mask is not required to generate a silicide film.

In a semiconductor process, when a silicide pattern that cannot be generated by saliicide is required, a method of using a mask during the silicide process is applied, but the present invention proposes to generate a barrier film while utilizing a silicide mask that is already in use. That is, this is achieved through a process of additionally defining a barrier film pattern on an already in-use mask, so that no additional mask or additional process is required.

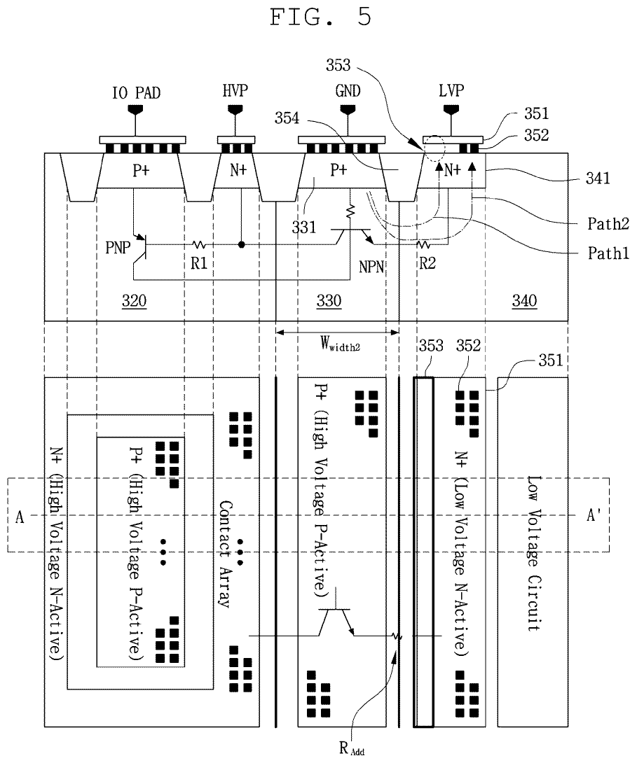

FIG. 5 is a structure of another embodiment of a semiconductor substrate including a latch-up circuit capable of suppressing a trigger according to the present invention.

The upper part of FIG. 5 is a vertical cross-sectional view of the semiconductor substrate, and the lower part is a plan view.

Referring to FIG. 5, according to another embodiment of the present invention, a structure of a semiconductor substrate is formed with a contact filler 352 in a space between a contact line 351 and an active region 341, and the contact filler 352 performs a function of electrically connecting the contact line 351 and the active region 341.

The inside of the dotted line circle in FIG. 5 is where the blocking film 353 illustrated in FIG. 4 was formed, but in this embodiment, instead of forming the blocking film 353 to generate an additional resistance component, it is proposed to generate an additional resistance component by adjusting the number and position of the contact fillers 352 in the process of generating the contact fillers 352.

That is, by not generating the contact filler 352 near the field oxide film 354 and forming the contact filler 352 only far from the field oxide film 354, an additional resistance component can be generated by the first path (Path 1).

The plan view and cross-sectional view of FIGS. 4 and 5 are simply illustrated to help understand the present invention, and since a person skilled in the art can easily understand the technical contents of FIGS. 4 and 5, they are not described in detail here.

Referring to FIG. 1 illustrating a conventional technology and FIGS. 4 and 5 illustrating an embodiment of the present invention, the width (W_{width2}) of the high-voltage P-type well according to the structure of the present invention is narrower than the width (W_{width1}) of the high-voltage P-type well according to the conventional technology, but has the advantage of suppressing the trigger of the latch-up circuit.

### INDUSTRIAL APPLICABILITY

The present invention relates to a technology capable of suppressing the trigger of a parasitic latch-up circuit of a semiconductor substrate, and can be applied to all substrates on which semiconductor circuits are manufactured industrially.

1.-10. (canceled)

11. A semiconductor substrate structure comprising a first transistor, a second transistor, and a first emitter resistance, wherein the structure includes a latch-up prevention circuit configured to suppress triggering, wherein the latch-up prevention circuit comprises a structure that increases the resistance value of the emitter resistance formed between the second transistor and a low-voltage power supply, or comprises an additional resistance formed between the second transistor and the first emitter resistance.

12. The semiconductor substrate structure according to claim 11, wherein the emitter terminal and base terminal of the first transistor, and a first collector resistance, are formed in a first well region.

13. The semiconductor substrate structure according to claim 12, wherein a collector terminal of the first transistor and a base terminal of the second transistor are formed in a second well region.

14. The semiconductor substrate structure according to claim 13, wherein an emitter terminal of the second transistor is formed in a third well region.

15. The semiconductor substrate structure according to claim 14, wherein the first well region comprises a high-voltage N-type well region, the second well region comprises a high-voltage P-type well region, and the third well region comprises a low-voltage N-type well region.

16. The semiconductor substrate structure according to claim 15, wherein the first transistor is a PNP bipolar transistor, an emitter terminal thereof is connected to an input/output pad, a base terminal is connected to a high-voltage power supply, and a collector terminal is connected to a ground power supply (GND).

17. The semiconductor substrate structure according to claim 16, wherein the second transistor is an NPN bipolar transistor, a collector terminal thereof is connected to a high-voltage power supply, and a base terminal is connected to a ground power supply (GND).

18. The semiconductor substrate structure according to claim 17, wherein the first collector resistance is connected between the collector terminal of the first transistor and the low-voltage power supply, and the first emitter resistance has one end connected to the low-voltage power supply.

19. The semiconductor substrate structure according to claim 18, wherein the additional resistance is disposed between the emitter terminal of the second transistor and the other end of the first emitter resistance.

20. The semiconductor substrate structure according to claim 19, wherein the additional resistance is formed in a space between a contact line supplying the low-voltage power and an active region supplying power to the third well region by a blocking layer.

21. The semiconductor substrate structure according to claim 20, wherein the first emitter resistance has a resistance value proportional to the length between the active region formed in the second well region and the active region formed in the third well region.

22. The semiconductor substrate structure according to claim 21, wherein when charge carriers move between the active region formed in the second well region and the active region formed in the third well region along a plurality of conduction paths, a resistance value corresponding to a first path directly between the two active regions is smaller than a resistance value corresponding to a second path having a relatively longer conduction distance.

23. The semiconductor substrate structure according to claim 22, wherein the first and second conduction paths are determined by a location of a contact filler formed in a space between a contact line supplying the low-voltage power and the active region formed in the third well region.

24. The semiconductor substrate structure according to claim 23, wherein the contact filler comprises a conductive material such as metal, and is filled in a hole between the contact line and the active region formed in the third well region to electrically connect the contact line and the active region.

25. The semiconductor substrate structure according to claim 24, wherein a field oxide film is formed between the second well region and the third well region.

26. The semiconductor substrate structure according to claim 25, wherein the contact filler is not present in a region adjacent to the field oxide film, and is formed at a preset distance away from the field oxide film.

27. The semiconductor substrate structure according to claim 26, wherein a silicide layer is not formed in a lower region of the blocking layer so as to increase the sheet resistance of the diffusion region corresponding to the blocking layer, and the contact filler is not formed in this region, but is instead formed at a preset location away from the field oxide film to increase the charge movement path.

28. The semiconductor substrate structure according to claim 27, wherein the number of contact fillers is adjusted such that the resistance value of the first emitter resistance increases by a predetermined amount.

29. A semiconductor substrate structure comprising a first transistor, a second transistor, and an emitter resistance, wherein the structure includes a latch-up prevention circuit configured to suppress triggering, wherein a first well region of the second transistor serves as a base region, and a second well region of a different conductivity type than the first well region serves as an emitter region, wherein the latch-up prevention circuit comprises: at least one of the number of contact fillers formed between a power-supplying active region formed in the second well region and a contact line located above the power-supplying active region, the location of the contact fillers, and a blocking layer covering part of the power-supplying active region, thereby increasing a resistance value of the emitter resistance or including an additional resistance.
